(19) United States
(12) Patent Application Publication
(10) Pub. No.: US 2005/0093170 A1
(43) Pub. Date: May 5, 2005

(54) Integrated interconnect package

(75) Inventors: Navinchandra Kalidas, Houston, TX (US); Jeremias Libres, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/695,714

(22) Filed: Oct. 29, 2003

(51) Int. Cl. H01L 21/44; H01L 23/52

(52) U.S. Cl. 257/778; 257/787; 438/108

(57) ABSTRACT

An integrated interconnect package for a semiconductor die and a method for assembling the die into the integrated interconnect package. The method may comprise placing the active face of the die onto an adhesive disposed on a sacrificial carrier, and applying an encapsulant over the backside of the die, forming a substantially rigid assembly structure. The assembly structure is separated from the adhesive, and an insulating material is applied to the active face of the die and patterned by a photolithography operation, creating at least one opening through the insulating material for exposing at least one die bond pad. A conductive material is then applied over the insulating material, flowing into the openings to contact the bond pads. The conductive material is then patterned by a photolithography operation, removing at least a portion of the conductive material to create a plurality of electrical traces and package terminals.

### BACKGROUND OF THE INVENTION

Integrated circuits are fabricated on the surface of a semiconductor wafer in layers and later singulated into individual semiconductor devices, or “dies.” Many fabrication operations are repeated numerous times, constructing layer after layer until fabrication is complete. Metal layers (which typically increase in number as device complexity increases) include patterns of conductive material that are insulated from one another vertically by alternating layers of insulating material. Vertical, conductive tunnels called “vias” typically pass through insulating layers to form conductive pathways between adjacent conductive patterns. Since the material of a semiconductor wafer—commonly silicon—tends to be relatively fragile and brittle, dies are often packaged in a protective housing before they are interconnected with a printed circuit board (PCB).

Referring now to FIG. 1, a cross-sectional view is shown of a flip-chip die 110 assembled into a package 100. Flip-chip interconnect technology allows a die 110 (or “chip”) to be mechanically and electrically connected to a printed circuit board (PCB) or package substrate 120 through an array of solder bumps 152 on the active face 112 of the die. As the entire active face 112 of the die 110 (and not just the periphery) can be used for interconnections, this technique increases the number of connections that can be made for a given die size over a conventional peripherally leaded package. Further, the package size may be greatly reduced, as placing the electrical interconnects between the die 110 and package substrate 120 underneath the die saves peripheral space around the die. The die 110 is first “bumped,” or patterned with metallic bumps 152, which will later attach the die a matching pattern of bumps on the package substrate 120.

After bumping, the die 110 is typically attached to the package substrate 120 facedown (or “flipped”) by slightly melting the solder bumps 152 in an oven reflow process, affixing them to the upper surface 134 of the substrate. The solder bump area is often reinforced by introducing an epoxy underfill 130 between the die 110 and the package package substrate 120 in order to improve solder joint reliability. After attachment, the die 110 is typically encapsulated by molding an encapsulant, or “mold compound” 170 over the die, shielding the die from physical damage. Conductive vertical columns, or substrate vias 124, allow electrical interconnection through the many layers of the package substrate 120. Solder balls 180 attached to the bottom surface 136 of the package substrate 120 may allow electrical communication between the die 110 and the board 190 to which the package 100 is mounted. However, the distance between the active surface 112 of the die 110 and the underlying board 190 may contribute to a high inductance and capacitance.

Traditional semiconductor assembly often involves shipping fabricated wafers from wafer fab facilities to assembly factories, which are often on a different continent and thus inherently costly and time-consuming. The equipment to perform traditional assembly, including die bumping and assembly into a package generally involves a high amount of capital investment, and these costs are passed on to customers and end users. Costs may also rise if a particular high-end assembly tool is running at or near capacity, with many assembly sites charging a premium for packaging devices using these tools. Consequently, reducing the quantity of manufacturing equipment, or tools, needed for packaging of dies would be desirable.

It is desired to devise a method for packaging dies incorporating the aforementioned benefits, including a scalable method of packaging flip-chip dies using low-end fabrication equipment to improve manufacturing throughput and improve overall package electrical performance.

### BRIEF SUMMARY OF THE INVENTION

Disclosed are an integrated interconnect package for a semiconductor die, and a method for assembling the die into the integrated interconnect package. One embodiment of the method comprises layering an insulating material over the active face of a singulated semiconductor die, and layering a conductive material over the insulating material, wherein a portion of the conductive material contacts at least one die bond pad.

In another embodiment, an insulating material is applied to the active face of the die and patterned by a photolithography operation to create at least one opening through the insulating material for exposing at least one die bond pad. A conductive material is then applied over the insulating material, flowing into the openings to contact the die bond pads. The conductive material is then patterned by a photolithography operation, removing at least a portion of the conductive material to create a plurality of electrical traces and package terminals. In an alternative embodiment, the application and patterning of the insulating and conductive layers may be repeated, creating a plurality of alternating insulating and conductive layers, for more complex routing. In some configurations, solder balls are affixed to the package terminals, for connection to a printed circuit board (PCB).

### BRIEF DESCRIPTION OF THE DRAWINGS

For a detailed description of the preferred embodiments of the invention, reference will now be made to the accompanying drawings in which:

FIG. 1 is a cross-sectional view of a flip-chip die assembled into a package;

FIG. 2 is a top view of an assembly structure carrier;

FIG. 3A is a top view of an adhesive mounted to the assembly structure;

FIG. 3B is a top view of the adhesive;

FIG. 3C is an exploded view of a die-sized area of FIG. 3B;

FIG. 4 is a top view of a semiconductor wafer and the assembly structure;

FIG. 5A is a top view of the assembly structure comprising an array of mounted dies;

FIG. 5B is a cross-sectional view of FIG. 5A taken along line 5B-5B;

FIG. 5C is a cross-sectional view of FIG. 5A taken along line 5B-5B, including an optional die stiffener;

FIG. 6A is a top view of the assembly structure after an encapsulation process;

FIG. 6B is a cross-sectional view of FIG. 6A taken along line 6B-6B;

FIG. 7 is a cross-sectional view of the assembly structure during carrier removal;

FIG. 8A is a cross-sectional view of the assembly structure during adhesive removal;

FIG. 8B is a bottom view of FIG. 8A after adhesive removal;

FIG. 9A is a cross-sectional view of the assembly structure after the application of an insulative layer;

FIG. 9B is a bottom view of FIG. 9A;

FIG. 10A is a cross-sectional view of the assembly structure after patterning and removal of a portion of the insulative layer;

FIG. 10B is a bottom view of FIG. 10A;

FIG. 11A is a cross-sectional view of the assembly structure after the application of a conductive layer;

FIG. 11B is a bottom view of FIG. 11A;

FIG. 12A is a cross-sectional view of the assembly structure after patterning and removal of a portion of the conductive layer;

FIG. 12B is a bottom view of FIG. 12A;

FIG. 13A is a cross-sectional view of the assembly structure after attaching solder balls;

FIG. 13B is a bottom view of FIG. 13A;

FIG. 14A is a bottom view of the assembly structure during singulation;

FIG. 14B is an exploded view of a singulated package as outlined in FIG. 14A

FIG. 14C is a cross-sectional view of a package as outlined in FIG. 14A taken along line 14C-14C;

FIG. 15A is a cross-sectional view of a singulated package mounted to a PCB;

FIG. 15B is a bottom view of FIG. 15A with solder balls removed;

FIG. 16A is a cross-sectional view of a first embodiment of an integrated interconnect package;

FIG. 16B is a bottom view of FIG. 16A;

FIG. 17 is a bottom view of a second embodiment of an integrated interconnect package;

FIG. 18A is a cross-sectional view of a third embodiment of an integrated interconnect package; and

FIG. 18B is a bottom view of FIG. 18A.

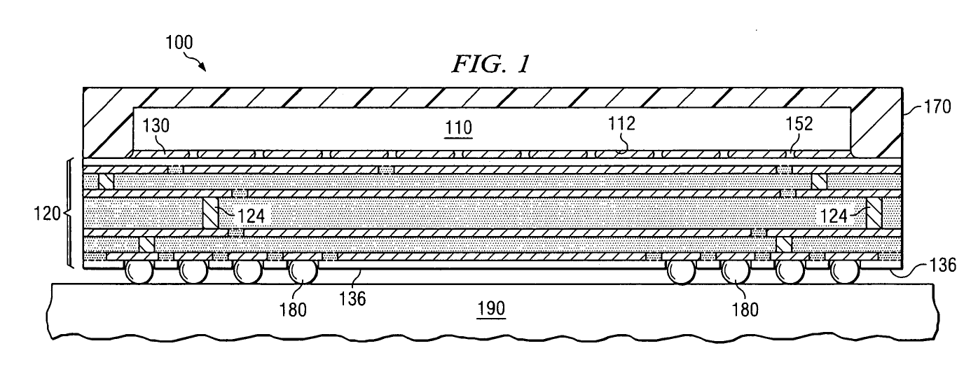

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct connection. Thus, if a first device couples to a second device, that connection may be through a direct connection, or through an indirect electrical connection via other devices and connections.

The term “integrated circuit” refers to a set of electronic components and their interconnections (internal electrical circuit elements, collectively) that are patterned on the surface of a silicon, or other suitable, semiconductor substrate. The term “semiconductor device” refers generically to an integrated circuit (IC), which may be integral to a semiconductor wafer, singulated from a wafer, or packaged for use on a circuit board. The term “die” (“dies” for plural) refers generically to an integrated circuit, in various stages of completion, including the underlying semiconductor substrate and all circuitry patterned thereon. The term “wafer” refers to a generally round, single-crystal semiconductor substrate.

The term “interconnect” refers to a physical connection providing electrical communication between the connected items. The term “packaged semiconductor device” refers to a die mounted within a package, as well as all package constituent components. The term “semiconductor package” refers generically to the components for encapsulating and interconnecting a die to a printed circuit board. To the extent that any term is not specially defined in this specification, the intent is that the term is to be given its plain and ordinary meaning.

### DETAILED DESCRIPTION OF THE PREFERRED EMBODIMENTS

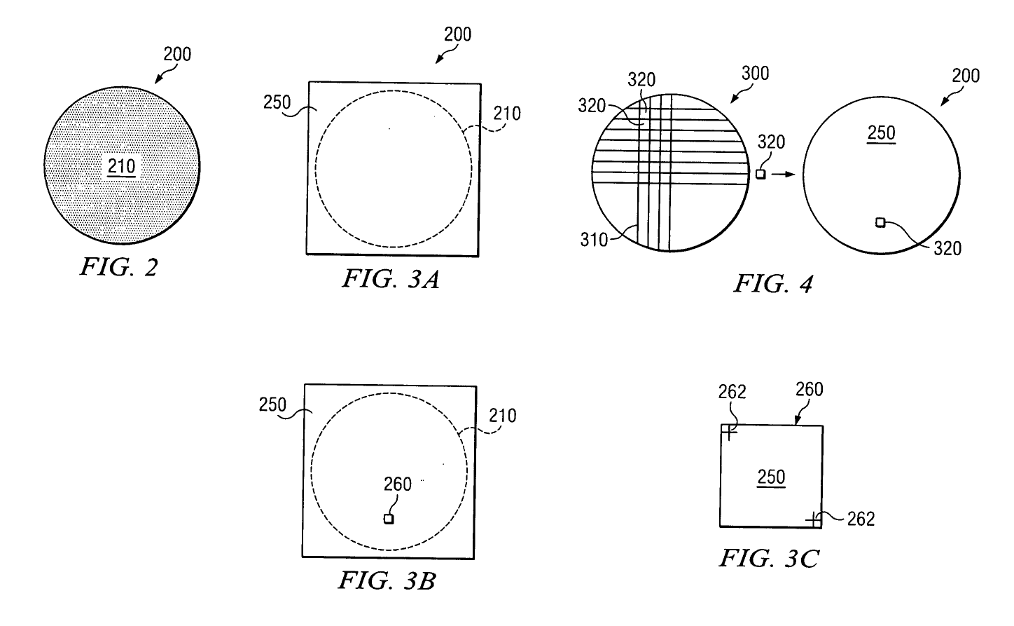

FIG. 2 shows a top view of an assembly structure 200 comprising a sacrificial carrier 210 upon which the integrated interconnect package will be constructed. In further stages of assembly, the assembly structure 200 will come to comprise several additional components, to be discussed below. It will be understood that, when used, a “top” view denotes an assembly structure 200 oriented for receiving an integrated-circuit die facedown. The carrier 210 is preferably a rigid, round sheet of material suitable for use with existing wafer fabrication (“fab”) equipment, or toolsets, which are designed to handle round semiconductor wafers. Aluminum is a preferred, low-cost material that could be used as the sacrificial carrier material. It will be understood that while a round aluminum wafer is preferred as the sacrificial carrier 210, other shapes (e.g., a strip) and materials may be used, such that the carrier 210 is suitable for processing by existing toolsets.

Referring now to FIG. 3A, in a first embodiment, an adhesive 250, preferably a double-sided assembly tape such as tape marketed under the trade name Adwill® by Lintec, is adhered to the sacrificial carrier 210 (shown in dashed lines). FIG. 3C is an exploded view of a die-sized area 260 of the adhesive 250 shown in FIG. 3B. As shown in FIG. 3C, the adhesive 250 preferably has the capacity to be pre-printed or otherwise marked with at least one fiducial 262, a positioning mark, often in the shape of a cross or bracket, for aiding the positioning of a semiconductor die. Fiducials 262 may be created by screen-printed or any other standard labeling method used in the adhesive industry.

FIG. 4 shows a top view of a semiconductor wafer 300 and the assembly structure 200. Scribe streets 310 have been cut through the wafer 300 singulating the wafer into individual semiconductor dies 320. Each die 320 is transferred to the surface of the assembly structure 200, adhering to the adhesive 250.

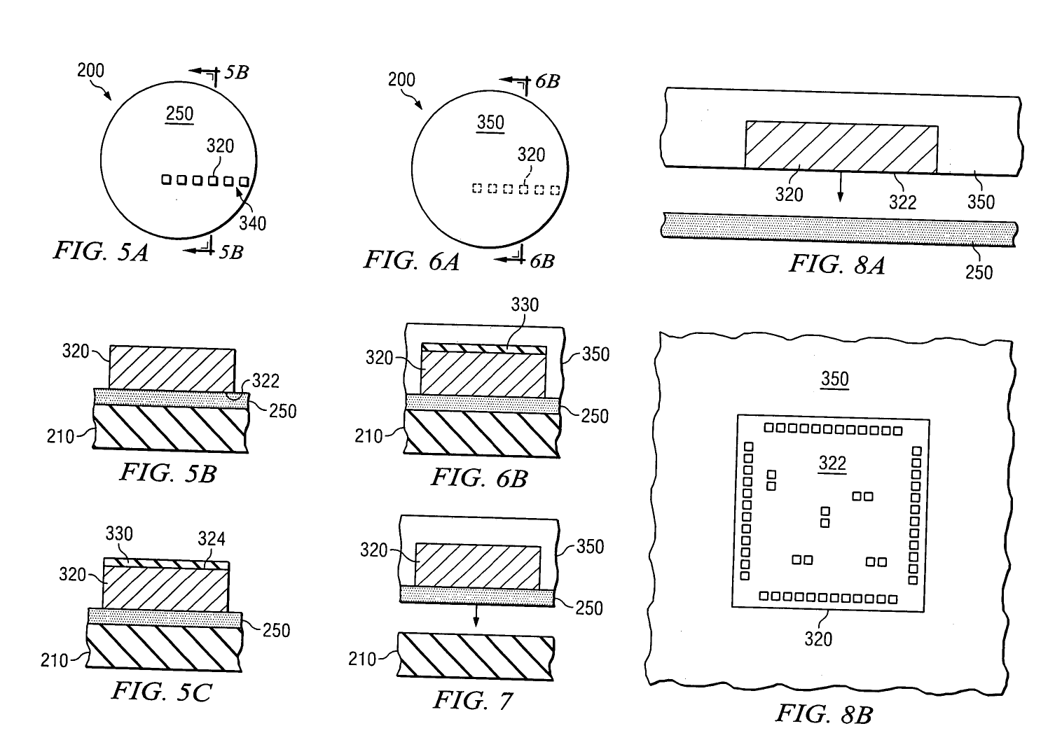

As shown in the top and cross-sectional views of FIGS. 5A and 5B, respectively, the individual dies 320 are mounted facedown on the exposed adhesive 250, such that the active face 322 of the dies adheres to the adhesive. Views in which the die 320 is facedown are designated as “top” views, while views in which the die is face-up are denoted as “bottom” views. Sacrificial carrier 210 serves as a backbone for the die mounting process. Prior to singulating the wafer 300, the individual dies 320 may have been tested for electrical performance, such that only known good dies, or functioning dies, are picked for transferring to the adhesive 250. Preferably, the dies 320 are placed in an array one at a time (see FIG. 5A), with spacing 340 between each die determined largely by the complexity of the circuitry to be patterned around the die in later steps, as well as the width of the sacrificial scribe street 310 (see FIG. 4). For dies 320 with a relatively high pincount, the spacing 340 between each die may increase, as more complex routing may need to be created.

In an optional step, as shown in FIG. 5C, a stiffener 330 may be applied to the backside 324 of the die 320. The stiffener 330 is preferably copper, but may be any material suitable for adding structural rigidity to the die 320. More preferably, the stiffener 330 is a material with a relatively high thermal conductivity, such that it may serve as a heat spreader, allowing greater heat dissipation from the die 320. The stiffener material may be dispensed, such as by a sputtering process, or may be positioned mechanically. For a die 320 with an exemplary thickness between 11-15 mils (where one mil is roughly equivalent to 0.025 millimeters), the stiffener 330 may be about 5 mils thick, with the thickness varying according to die size as well as thermal and rigidity concerns. In a completed integrated interconnect package, the stiffener 330 may be exposed or concealed, depending on the needs of the particular device.

Referring now to FIGS. 6A and 6B, in top and cross-sectional views, respectively, an encapsulant 350 is applied over the assembly structure 200, effectively encapsulating the dies 320 and at least a portion of the stiffener 330, if present. The encapsulant 350 is preferably a mold compound or epoxy, although a high-thermal-conductivity mold compound with high filler loading may be selected. In a molding process, the encapsulant 350 is a solid dispensed over the dies 320 under pressure. Depending on the configuration of the assembly structure 200, the encapsulant may be a free-flowing dispensed compound, such as a “glob-top” encapsulant. After molding or dispensing, the encapsulant 350 may be cured by being subjected to elevated temperatures.

After encapsulation, the assembly structure 200 may be sufficiently rigid that the sacrificial carrier 210 can be removed, as shown in the cross-sectional view of FIG. 7. Carrier removal may be performed manually, but is preferably automated. Exposing the assembly structure 200 to ultraviolet (UV) light reduces adhesion of the adhesive 250, such that the carrier 210 can be more easily detached.

In a subsequent process, as shown in FIG. 8A, the adhesive 250 is removed by a similar process to the carrier removal. As shown in the bottom view of FIG. 8B, after the adhesive 250 is removed, the active surface 322 of the die 320 is exposed for further processing most likely in a configuration in which the active surface 322 faces upward. Thus, while denoted as “bottom” views, the active surfaces exposed in bottom views may actually be face-up during further processing.

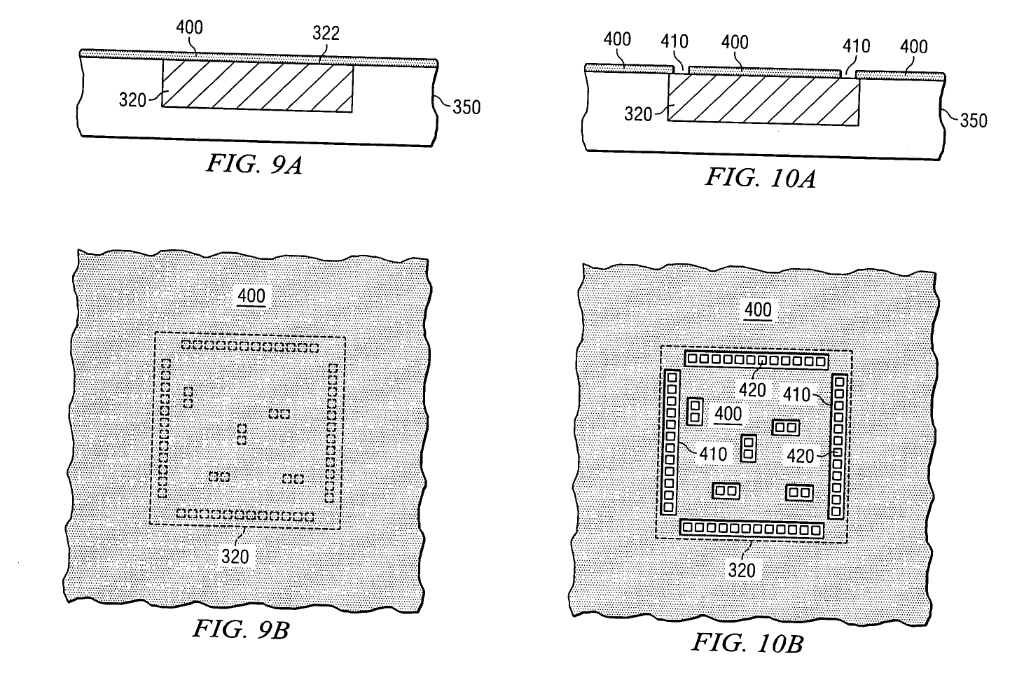

Referring now to FIGS. 9A and 9B, cross-sectional and bottom views are shown, respectively, of an insulating material layering process. After exposing the die 320, the assembly structure 200 is preferably coated with an insulating material 400, which adheres to the exposed surfaces of the die 320 and encapsulant 350. The insulating material 400 serves as a dielectric, and is preferably a layer of polyimide, benzocyclobutene (BCB) or polybenzoxazole (PBO), although other electrically insulative materials may be used. The insulating material 400 may be applied by screening, spinning, deposition or other application process suitable to the material chosen. For a die 320 with an exemplary thickness of 11-15 mils, the insulating layer 400 may be between about 5 microns (μm) and about 7 μm thick, where one mil is equivalent to 25.4 μm. FIG. 9B shows the position of a single die 320 below the layer of insulating material 400.

The insulating layer 400 may thereafter be patterned and a section removed creating openings 410 that expose the material underneath (i.e., the die 320), as shown in FIGS. 10A-10B. The insulating layer 400 is preferably a material having photoresist properties and may be patterned using either a positive or negative photoresist process. In one exemplary patterning process, the photoresist material (i.e., the insulating layer 400) is exposed to light through a mask. The photoresist is then subjected to a developer chemical, and areas exposed to the light are removed (i.e., a positive photoresist process) or alternatively, areas masked from the light are removed (i.e., a negative photoresist process). FIG. 10B is a bottom view showing openings 410 created around die bond pads 420, conductive areas corresponding to electrical termination points on the die 320.

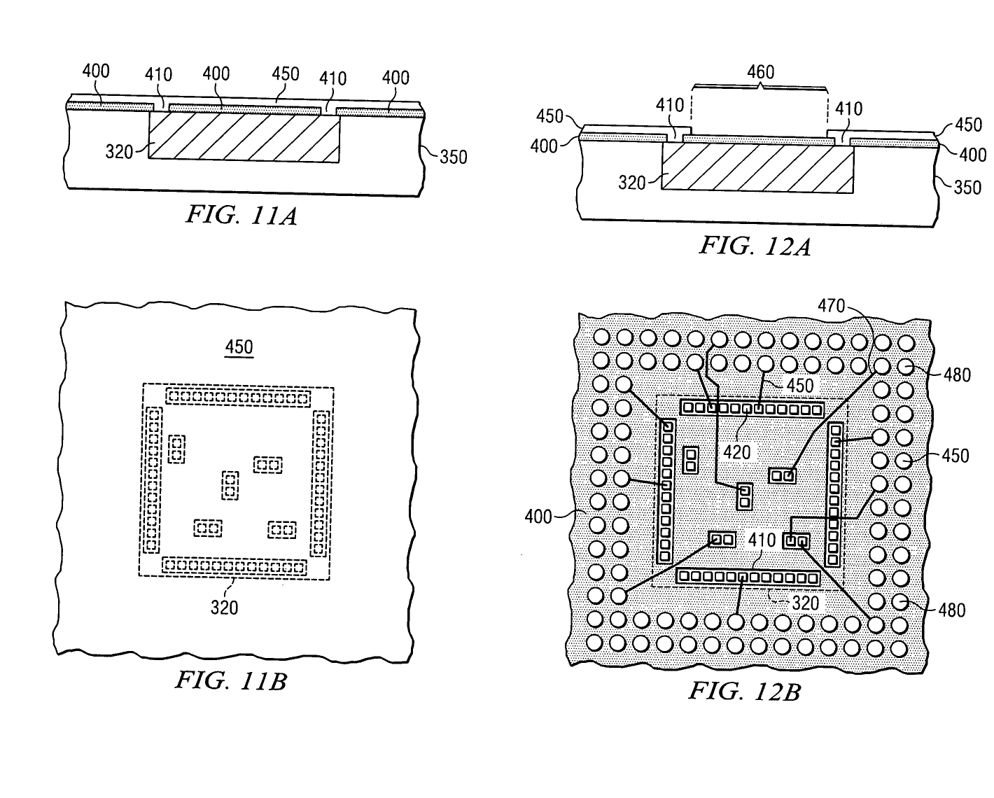

Following removal of a portion of the insulating material 400, a conductive material 450 is applied to the assembly structure 200, as shown in FIGS. 11A-11B. The conductive material 450 is deposited or otherwise placed into the openings 410 that were produced in the underlying layer of insulating material 400 and electrically contacts the exposed areas of the die 320. While the conductive material 450 is preferably copper, it may be another electrically conductive or semi-conductive material that will adhere to insulating layer 400. For a die 320 with an exemplary thickness of 11-15 mils, the conductive layer 450 may be between about 10 μm and about 12 μm thick, although this thickness may vary according to the material chosen as well as electrical needs. The conductive material 450 may be applied by deposition, sputtering, electroplating or another suitable method for adhering the material to the insulating layer 400.

Referring now to FIGS. 12A-12B, cross-sectional and bottom views are shown, respectively, of the assembly structure 200 after a metal patterning and removal of a portion of the conductive material. After depositing the conductive layer 450 onto the structure 200, the metal is preferably subjected to a photolithography and etch operation, removing unneeded areas of metal and creating openings 460 in the conductive layer. As shown in FIG. 12B, relatively small areas of the patterned conductive material 450 may remain, forming traces 470 and package terminals 480 over the exposed insulating material 400. Collectively, insulating layers 400 and conductive layers 450 form an interconnect portion for routing traces from die bond pads 420 to a PCB (not shown). More specifically, traces 470 are routed to pass through an opening (e.g., opening 410), in the insulating layer 400 to connect a die bond pad 420 to an appropriate package terminal 480. The package terminals 480 are conductive areas, which serve as electrical termination points for signals or other pins associated with die bond pads 420 on a die 320.

Different materials may have significantly dissimilar coefficients of thermal expansion (CTE), a value associated with the amount a material expands per degree of temperature increase. As dies 320 tend to heat up during operation, the various materials in a surrounding semiconductor package may expand at different rates. Silicon has a CTE of about 3 ppm/° C. An epoxy may have a CTE of about 50 ppm/° C., and is thus much more expansive than silicon when heated. Thus, the presence of a nearly continuous insulating layer 400 below the traces 470 affords some reliability from failure caused by differential expansion, in that each relatively narrow trace does not have to pass over two distinctly different materials, such as the die 320 (e.g., silicon) and the encapsulant 350 (e.g., an epoxy).

When two materials having significantly dissimilar CTE values are positioned adjacent to one another and subjected to a temperature increase, relatively high material stresses may result at the interface between the two materials. As each trace 470 may only be a few microns wide (although other trace widths may be acceptable as well), it is preferable to shield these relatively delicate structures from such areas of high material stress. Traces 470 that are cracked, severed, or otherwise damaged may affect the overall operation of a packaged semiconductor device. By forming the traces 470 over a substantially continuous material (e.g., the insulating material 400), the traces may be reasonably shielded from any underlying CTE mismatch and the associated stresses, potentially contributing to increased package reliability. A subsequent application of an insulating layer to protect traces 470, followed by a patterning operation to expose package terminals 480, may be performed if desired.

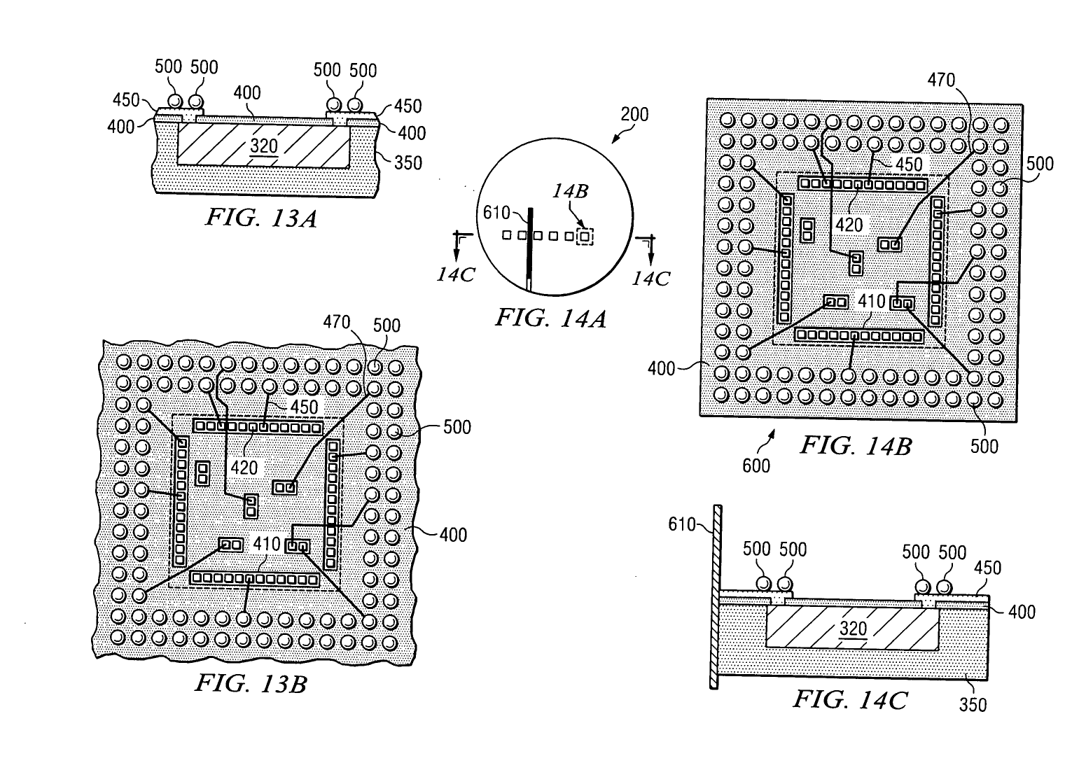

Referring now to FIGS. 13A and 13B, cross-sectional and bottom views are shown, respectively, of the assembly structure 200 after an optional ball-attach operation. In a preferred embodiment, solder balls 500 are adhered to the conductive metal 450, e.g., with one solder ball adhered to each package terminal, as shown in FIG. 13B. Solder balls may be a eutectic material, or alloy, preferably a tin-lead mixture. A flux, paste or epoxy may be dispensed onto each package terminal to aid in ball adhesion. Solder balls 500 are attached to the underlying conductive metal in an oven reflow process, in which the balls are subjected to elevated temperatures. Although the preferred embodiment shows solder balls 500, it will be understood that other interconnection measures, such as leadless connections, terminating points or solder columns, may be utilized without departing from the spirit of the invention.

After packaging of the die 320 is complete, the assembly structure 200 may be singulated into individual mechanically encased semiconductor die assemblies, or integrated interconnect packages 600, as shown in FIGS. 14A-14C. A wafer-dicing blade 610 is preferably used to saw through the assembly structure 200, between each package 600. The blade 610 is a thin disc having an abrasive edge that is rotated at high speed. Other measures for singulating the individual packages 600 from the assembly structure 200 may be used without departing from the spirit of the invention.

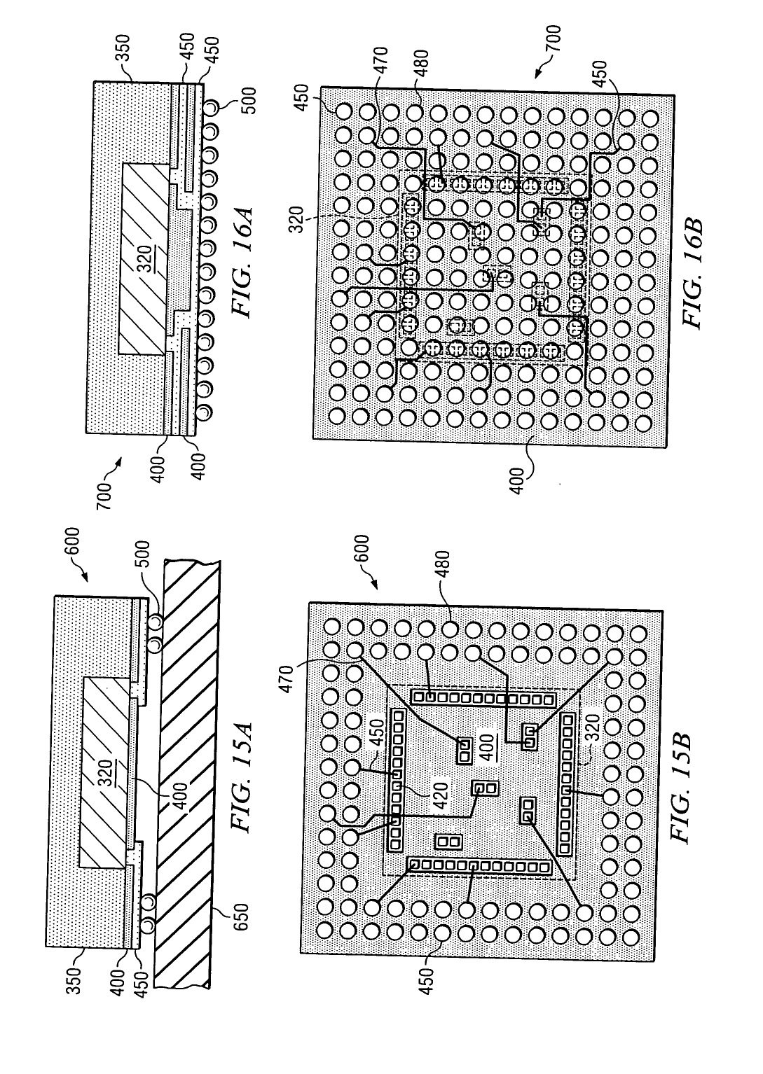

Although each package 600 is shown to include one die 320, in an alternative embodiment, more than one die 320 and associated circuitry may be included in each singulated package 600, forming a multi-chip module (MCM). Each singulated package 600 is subsequently ready for mounting on a printed circuit board (PCB) 650, as shown in FIG. 15A. Solder balls 500 may be attached to a PCB 650 in a similar manner to how they are affixed to the assembly structure 200 using an oven reflow process. When mounted to a PCB 650, the conductive metal 450 forms a pathway of electrical communication between the die 320 and the PCB, as well as to the electrical device (not shown) in which the PCB is eventually installed.

For a relatively low-pincount die 320, or a die having comparatively few die bond pads 420, the die may be routed using a single application each of insulating layer 400 and a conductive layer 450. Referring now to FIG. 15B, the embodiment shown-in FIG. 14B is shown with solder balls removed for clarity. A depopulated array of package terminals 480 is shown, a configuration in which the terminals are disposed mainly on the periphery of package 600. As previously mentioned, a final layer of insulating material (not shown) may be applied over the outermost conductive layer 450, protecting traces 470 from potential damage.

For a die with a higher pincount, a more complex integrated interconnect package 700 may be created, as shown in the cross-sectional and bottom views, respectively, of FIGS. 16A and 16B. In the alternative embodiment of FIG. 16A, the operations of applying an insulating layer 400, patterning and removal of the insulating layer, applying a conductive layer 450, and patterning and removal of a portion of the conductive layer are repeated. Consequently, two insulating layers 400 and two conductive layers 450 are formed, in an alternating pattern. This process may be repeated as many times as is necessary to produce the minimum number of insulating layers 400 and conductive layers 450 required for routing traces from die bond pads (not shown in FIG. 16B) on the die 320 to package terminals 480. The alternative embodiment shown in FIG. 16B is a full array of package terminals 480, a configuration in which the terminals are disposed over the die 320 and substantially over the entire surface area of package 700.

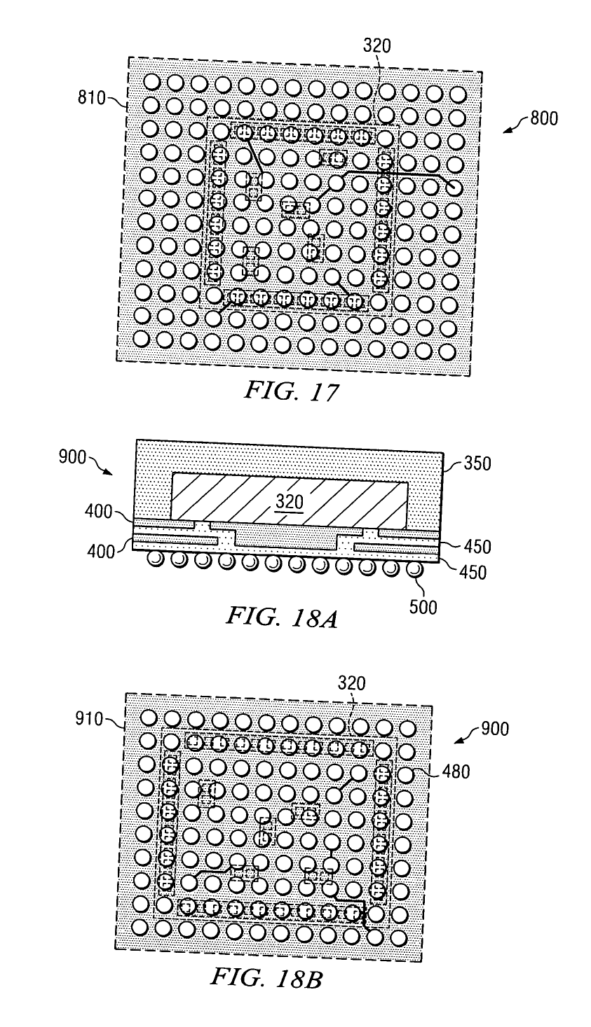

An integrated interconnect package in accordance with the preferred embodiments may be singulated into a custom shape. Referring now to FIG. 17, an integrated interconnect package 800 with a more rectangular footprint may be created, especially if the die 320 around which the package is created has a relatively high aspect ratio. In still another embodiment, as shown in FIGS. 18A and 18B, a chip-scale integrated interconnect package 900, or package with a footprint 910 only slightly larger than the die 320, may be created. Accordingly, the integrated interconnect package allows high routing flexibility by the ability to construct several alternating layers of insulating material 400 and conductive material 450, and allows package terminals 480 to utilize substantially the entire area of the package. As such, many different die sizes and pincounts can be accommodated by various package footprints.

A major benefit of the disclosed method is the ability to manufacture a die into a package using existing wafer fab equipment. An assembly site for packaging dies may be a separate facility to a wafer fab, and is often distant or owned by a subcontractor. Additionally, an entirely different family of toolsets may be required for conventional package assembly, and may contribute to increased capital investment, labor and overhead costs. The relatively large dimensions to be patterned using the disclosed assembly method may produce patterns an order of magnitude or larger than required in a wafer-fab process. As such, low-end fab equipment, older tools for producing dies with larger line widths, may be suitable. High-end fab equipment, or toolsets dedicated to producing the most advanced chips, may be capable of fabricating dies with the smallest circuit geometries, and as such, tend to be the most expensive to purchase, maintain and operate. Depending on the interconnect method (e.g., solder balls) chosen for connecting the package to a PCB, the package interconnections may be created with wafer fab equipment as well.

As semiconductor technology moves in the direction of smaller dies with smaller internal circuit geometries, high-end fab equipment is often in the most demand, with low-end equipment often sitting idle or underused. Excess capacity on low-end fab equipment can be taken advantage of to rapidly assemble relatively low-cost packaged dies in accordance with the preferred embodiments discussed above, potentially without the need for shipping wafers to a distant assembly site. Existing fab processes, including photolithography operations (e.g., spinning on a film, exposing the film to a mask, and developing the pattern) as well as metal deposition, patterning and etch operations can easily be applied to producing an integrated interconnect package. Additionally, as wafer fab toolsets may be designed to produce much smaller dimensions than may be required for an integrated interconnect package, it is likely that the geometries produced will be very precise.

A number of other benefits may be achieved with the integrated interconnect package of the preferred embodiments. Wirebonding is a common method of electrically interconnecting a die to a package in which relatively thin wires are strung between the active face of a die and the package. However, these bond wires have a relatively high inductance and cannot be sandwiched by ground planes, which may shield an interstitial trace from external noise or electromagnetic interference. In the integrated interconnect package, a trace can be surrounded by one or more ground planes or may be positioned in proximity to one. In addition, due to the relatively thin insulative and conductive layers possible with the method of the preferred embodiments, package power and ground planes may be positioned close enough to one another so as to enhance electrical performance. Disposing the power and ground planes closer to one another may lower the package inductance while increasing the capacitance, both of which are generally beneficial to an electronic device.

An integrated interconnect package constructed in accordance with embodiments of the invention also may largely eliminate or reduce vertical travel of routing for packages with single or few conductive layers. Conventional package substrates generally route signals through several layers utilizing relatively high aspect ratio, inter-layer vias. As insulative layers in accordance with the preferred embodiments may be about 5-7 μm thick or less, the vertical distance a signal travels, even in a multi-layered integrated interconnect package, would be small. Further, conventional vias may contribute a significant amount of noise, in terms of inductance and capacitance, due to their reasonably tall profiles. In a single-metal-layer integrated interconnect package, the trace metallization is on the same layer as the package terminals, and is adjacent to the die bond pads, eliminating via height in some cases. Consequently, substantially no vertical travel is required between the signal traces and the package terminals.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. A method comprising:
adhering the active face of a singulated semiconductor die to a sacrificial carrier;
encapsulating a backside of the singulated semiconductor die having a bond pad, and thereby forming a substantially rigid assembly structure;
separating the assembly structure from the sacrificial carrier to expose the active face of the singulated semiconductor die;
layering an insulating material over the active face of the singulated semiconductor die; and
layering a conductive material over the insulating material, wherein a portion of the conductive material contacts the die bond pad.

2. The method of claim 1, wherein layering the insulating material further comprises creating at least one opening in the insulating material to expose at least one die bond pad.

3. The method of claim 1, wherein layering the conductive material further comprises creating at least one conductive trace in the conductive material.

4. The method of claim 3 further comprises creating a plurality of package terminals.

5. The method of claim 1, wherein layering the insulating material over the active face of the singulated semiconductor die further comprises layering a material selected from a group consisting of polyimide, benzocyclobutene (BCB) and polybenzoxazole (PBO).

6. The method of claim 1, wherein layering the conductive material further comprises layering copper over the insulating material.

7-20. (canceled)

21. A method comprising:
providing a semiconductor die having a active face, a back side and a bond pad;
adhering the active face of the semiconductor die to a carrier;
encapsulating the backside of the semiconductor die with an encapsulant;
hardening the encapsulant;
removing the carrier from the active face of the semiconductor die;
applying a layer of insulating material over the active face of the semiconductor die; and
applying a layer of conductive material over the insulating material, wherein a portion of the conductive material contacts the bond pad.

22. The method of claim 20, further comprising creating an opening through the layer of insulating material.

23. The method of claim 20, further comprising creating a conductive trace in the layer of conductive material and a package terminal.

24. The method of claim 20, wherein the insulating material includes a material selected from a group consisting of polyimide, benzocyclobutene (BCB) and polybenzoxazole (PBO).

25. A method comprising:
providing a semiconductor die having a active face, edge surfaces, a back side and a bond pad;
attaching the active face of the semiconductor die to a carrier;
encapsulating the backside and the edge surfaces of the semiconductor die with an encapsulant; and
hardening the encapsulant.

26. A method comprising:
providing a semiconductor die having a active face, a back side and a bond pad;
attaching the active face of the semiconductor die to a carrier;
encapsulating the backside and the edge surfaces of the semiconductor die with an encapsulant;
hardening the encapsulant to form a disk-shaped assembly structure;
removing the carrier from the active face of the semiconductor die;
forming a first layer of insulating material over the active face of the semiconductor die;
forming an opening through the first layer of insulating material to uncover the bond pad;
forming a layer of copper over the insulating material;
forming a package terminal in the copper layer;
forming a cooper trace with which the bond pad and the package terminal are electrically coupled; and
applying a second layer of insulating material over the bond pad and the conductive trace.

27. The method of claim 26, wherein the insulating material includes a material selected from a group consisting of polyimide, benzocyclobutene (BCB) and polybenzoxazole (PBO).
